(19) United States
(12) Patent Application Publication
(10) Pub. No.: US 2023/0332331 A1
(43) Pub. Date: Oct. 19, 2023

(54) APPARATUS FOR GROWING CRYSTALS, HAVING A THERMAL CASING UNIT

(71) Applicant: EBNER Industrieofenbau GmbH, Leonding (AT)

(72) Inventors: Robert EBNER, Leonding (AT); Kanaparin ARIYAWONG, Leonding (AT); Ghassan BARBAR, Neunkirchen (DE); Chih-Yung HSIUNG, Leonding (AT)

(73) Assignee: EBNER Industrieofenbau GmbH, Leonding (AT)

(21) Appl. No.: 18/028,678

(22) PCT Filed: Sep. 23, 2021
(86) PCT No.: PCT/AT2021/060340

§ 371 Date: Mar. 27, 2023

(30) Foreign Application Priority Data
Sep. 28, 2020 (AT) A 50818/2020

(51) Int. Cl. C30B 35/00

(52) U.S. Cl. CPC C30B 35/002; C30B 35/007

(57) ABSTRACT

A device for growing crystals, includes a crucible and an enveloping unit surrounding it for the thermal insulation of the crucible The enveloping unit is held on the crucible in its position relative thereto by a holding unit The holding unit includes at least one holding element designed to be oblong and preferably non-rigid, having a first and second end section The holding element surrounds the enveloping unit circumferentially on the side facing away from the crucible and contacts it. The two end sections are coupled to one another, wherein a holding force acting on the enveloping unit in the radial direction is applied by the holding element

The invention relates to a device for growing crystals with a crucible and an enveloping unit surrounding it for the thermal insulation of the crucible.

Crystal growth is a process, in which an existing crystal increases in size as more molecules or ions accumulate on their position in the crystal lattice. A crystal is defined by atoms, molecules, or ions, which are arranged in an orderly, repetitive pattern. For the most part, this takes place in a crystal lattice, which extends in all three spatial dimensions. Hence, crystal growth differs from growth of a liquid droplet in that during growth, the molecules or ions must fall into the correct lattice positions in order for a well-ordered crystal to grow.

A single crystal or a monocrystalline solid is a material in which a crystal lattice of the entire sample is present continuous and uninterrupted to the edges of the sample without grain boundaries.

DE 10 2018 129 492 A1 of the same applicant describes a device and a method for growing crystals, in particular single crystals. For this purpose, the device comprises a chamber with an accommodation space, a crucible and an insulation material surrounding the crucible, so that the inner volume of the crucible is thermally insulated from the environment. A heating device is provided for heating the inner volume of the crucible. RF (radio frequency) heating devices, resistive heating devices and heating generators are suggested as heating elements of the heating device. The insulation material fills the intermediate space between the crucible and the inner chamber wall surface of the chamber wall. In this regard, the handling of the insulation material when removing the crystals produced in the crucible is disadvantageous.

EP 3 260 582 A4 also describes a device for producing crystals in a crucible, which is surrounded by an insulating layer formed by a graphite felt. The crucible along with the insulation material is inserted into a double quartz tube and is supported on a graphite supporting rod. The interior of the double quartz tube is further lowered to a pressure that is lower than the atmospheric pressure. By means of a heating device arranged around the double quartz tube, the crucible and its interior is heated for producing the crystals. Here, as well, the handling of the insulation material when removing the crystals produced in the crucible is difficult to carry out.

It was the object of the present invention to overcome the disadvantages of the prior art and to provide a device for producing crystals, by means of which a user is capable of performing easy mounting of the insulation material while achieving a secure mount during the production process.

This object is achieved by a device according to the claims.

The device according to the invention serves to grow crystals and comprises
a crucible, which crucible defines an outer lateral surface and moreover delimits an accommodation space with an axial extension between a bottom section and an opening section, wherein the accommodation space is designed for growing the crystals,
an enveloping unit, which enveloping unit covers the outer lateral surface at least in sections and is designed for thermally insulating the crucible, wherein it is further provided
that a holding unit is provided, by means of which holding unit the enveloping unit is held on the crucible in its position relative to the crucible,
that the holding unit comprises at least one holding element designed to be oblong and preferably non-rigid, having a first end section and a second end section spaced apart therefrom in its longitudinal extension,
that the at least one holding element surrounds the enveloping unit in a circumferential manner on the side facing away from the crucible and is arranged so as to contact the enveloping unit, and
that the first end section and the second end section are coupled to one another so as to be releasable as needed, and a holding force acting on the enveloping unit in the radial direction is applied by the at least one holding element.

The advantage achieved thereby is that this creates a quick and variable fastening means of the enveloping unit on the outside of the crucible. Thereby, the mounting and also the attaching can be carried out very easily and variably after filling the crucible with the base material for growing and forming the crystal. By providing the holding unit, by which a holding force acting on the crucible in the radial direction is applied to the enveloping unit, a relative, stationary holding and mounting of the insulating enveloping unit based largely on friction takes place. As the at least one holding element is designed to be oblong, it wraps around the outside of the enveloping unit at least once, wherein the two end sections of the respective holding element are connected to one another or coupled to one another. This creates a firm and tight wrapping, by means of which, on the one hand the mounting is achieved, and on the other hand, a removal or a replacement can be easily realized due to the coupling connection, which can be easily released as needed.

It can further be advantageous if the at least one holding element is formed by a graphite material. This allows a high temperature load and temperature effect.

A different embodiment is characterized in that the first end section and the second end section of the at least one holding element are knotted together. This allows omitting additional components for the mutual coupling and connection of the end sections.

A further possible embodiment has the features that a coupling device is provided for the at least one holding element, by means of which coupling device the first end section and the second end section of the at least one holding element are coupled to one another. By providing a separate coupling device, an even more secure connection between the two end sections of the holding element can be created. Furthermore, the coupling device may also be fixedly held or attached directly on the outer surface of the enveloping unit, and thus also serve for the positioned mounting of the holding element on the enveloping unit.

It is advantageous if the holding element designed to be oblong and preferably non-rigid is selected from the group of cord, rope, strip, belt, chain. Hence, the holding element most suitable for the relevant requirement and/or application can be selected. In the case of an arrangement of multiple holding elements, a combination of different holding elements is also possible.

A further design provides that multiple holding elements are provided and the holding elements are arranged so as to be spaced apart from one another in the direction of the axial extension of the crucible. Thereby, a more continuous fit of the enveloping unit on the crucible in the direction of the axial extension of the crucible can be achieved.

A different embodiment is characterized in that the holding unit comprises at least one guide element, which at least one guide element is arranged on the enveloping unit on the side facing away from the crucible, and the at least one guide element is configured to guide the at least one holding element in a predefined relative position with respect to the enveloping unit. Hence, a pre-positioning and also an inadvertent displacement of the holding element to a greater extent, in particular in a perpendicular arrangement of the crucible, can be prevented. Furthermore, the holding element may also remain on the holding unit even when the enveloping unit is removed from the crucible, and does not need to be handled separately upon renewed mounting in the insulation position.

A further preferred embodiment is characterized in that the enveloping unit has a first longitudinal edge section and a second longitudinal edge section when observed in the circumferential direction, and the longitudinal edge sections facing one another are arranged so as to overlap in the circumferential direction. Due to the mutual overlapping, an exact circumferential length adjustment of the enveloping unit can be omitted. Moreover, a continuous circumferential covering and a good thermal insulating effect associated therewith can thus be achieved.

It may be further advantageous if the enveloping unit protrudes beyond the crucible in the direction of its axial extension on at least one side facing away from the crucible. Hence, a great insulating effect can be achieved with an additional insulation element, particularly in the cover region. Furthermore, this also allows achieving a good and sufficient holding effect for the additional insulation element, particularly in the radial direction.

A different alternative embodiment is characterized in that the enveloping unit is formed by a graphite felt. With that, a high-temperature resistant material is used in order to be able to achieve a good thermal insulating effect even over a longer period.

A further possible and possibly alternative embodiment has the features that the graphite felt comprises at least one layer of a hard graphite felt. Thereby, a preformed insulating body can already be formed within certain limits.

A further design provides that the graphite felt comprises at least one layer of soft graphite felt. Thereby, a better and more continuous fit in terms of surface area on the crucible can be achieved.

A different embodiment is characterized in that the at least one layer of a hard graphite felt may be arranged closer to the crucible than the at least one layer of the soft graphite felt.

Thus, an even better and fuller fit on the crucible can be achieved.

A further preferred embodiment is characterized in that the crucible is formed by a material, which is selected from a group, which comprises metal-based, oxide-based, nitride-based, carbon-based, and dense graphite.

Furthermore, it may be advantageous if the crucible is designed to have multiple parts and comprises a crucible bottom part, at least one crucible wall part and a crucible cover part. Thus, a simpler design of the crucible parts can be realized. Furthermore, however, a kind of modular design may also be formed thereby, in order to thus be able to adapt the crucible dimensions to what is required for each process.

Another embodiment is characterized in that a positioning assembly is provided, by means of which positioning assembly at least the crucible bottom part and the at least one crucible wall part are positioned on the ends facing one another oriented in a predefined position relative to one another. Thereby, a mutual orientation and positioning of the individual components can be achieved in their assembled state.

A further possible embodiment has the features that a housing is provided, which housing defines an accommodation chamber, and the crucible along with the enveloping unit and the holding unit is accommodated in the accommodation chamber. This creates an additional envelopment for providing ambient conditions around the crucible required for the respective process.

A further embodiment provides that a heating device is provided, which heating device is preferably arranged circumferentially around the housing and is configured to provide thermal energy for the crucible. Thereby, the heat supply to the crucible and the base material located in the crucible for forming the crystal is made possible during operation.

For the purpose of better understanding of the invention, it will be elucidated in more detail by means of the figures below.

These show in a respectively very simplified schematic representation:

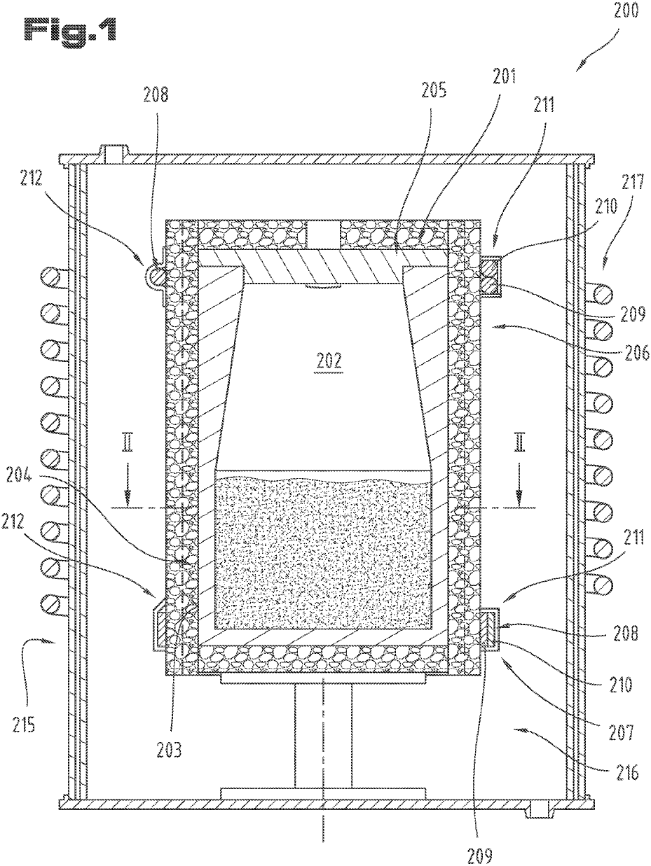

FIG. 1 an exemplary embodiment of a device for crystal formation with a crucible, on the outside of which an enveloping unit is held positioned by means of a holding unit thereon, in an axial section;

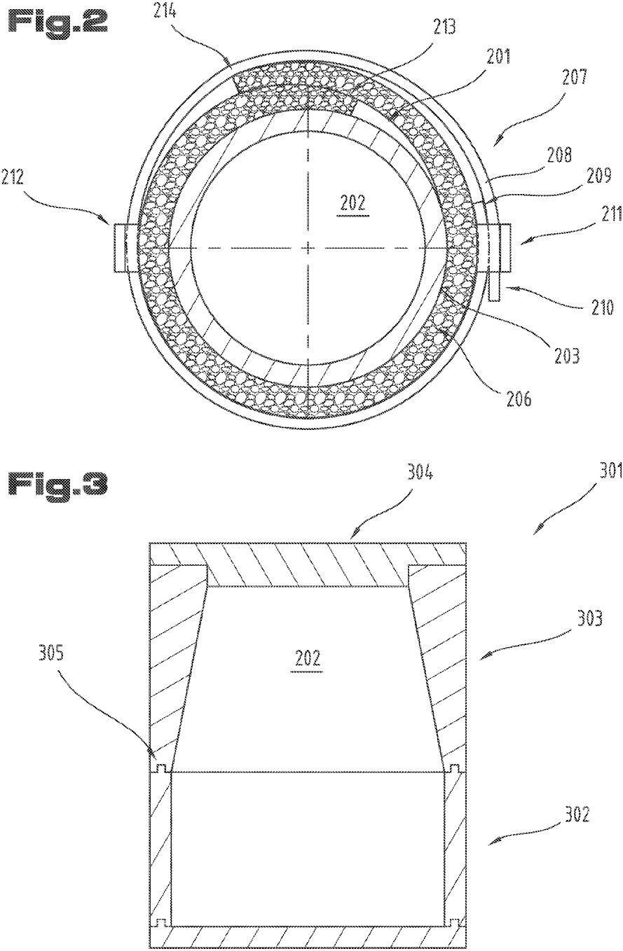

FIG. 2 the crucible according to FIG. 1, including its enveloping unit and holding unit alone, in a cross section according to lines II-II in FIG. 1;

FIG. 3 a further possible embodiment of a crucible, in an axial section.

First of all, it is to be noted that in the different embodiments described, equal parts are provided with equal reference numbers and/or equal component designations, where the disclosures contained in the entire description may be analogously transferred to equal parts with equal reference numbers and/or equal component designations. Moreover, the specifications of location, such as at the top, at the bottom, at the side, chosen in the description refer to the directly described and depicted figure and in case of a change of position, these specifications of location are to be analogously transferred to the new position.

The term “in particular” shall henceforth be understood to mean that it may refer to a possible more specific formation or more detailed specification of an object or a process step, but need not necessarily depict a mandatory, preferred embodiment of same or a mandatory practice.

In their present use, the terms “comprising”, “has”, “having”, “includes”, “including”, “contains”, “containing” and any variations thereof are meant to cover a non-exclusive inclusion.

A further term used is “optional”. This is understood to mean that this method step or this system component is principally present but depending on the operating conditions may be used although that does not necessarily have to be the case.

FIGS. 1 and 2 show a possible exemplary embodiment of a device 200 in different views, which device 200 serves to grow crystals or is configured therefor.

For this purpose, a crucible 201, among other things, is provided, which delimits an accommodation space 202 in its interior in a known manner. In most cases, the crucible 201 has a hollow-cylindrical cross-section, wherein cross-sectional shapes deviating therefrom, such as polygonal, oval or the like, are also possible. The crucible 201 moreover defines an outer lateral surface 203. The accommodation space 202 has an axial extension in the direction of its height, which extends between a bottom section 204 and an opening section 205. The crucible 201 with its accommodation space 202 is configured to grow crystals.

Furthermore, an enveloping unit 206 is provided for thermally insulating and providing insulation for the crucible 201, which enveloping unit 206 covers the outer lateral surface 203 of the crucible 201 at least in sections but preferably completely. The enveloping unit 206 surrounds the crucible 201 completely in the circumferential direction in this exemplary embodiment, in order to thus achieve a continuous and uninterrupted thermal insulation.

In the present exemplary embodiment, the enveloping unit 206 is formed by a graphite felt. The material graphite is well-suited for the largely hot temperatures and withstands them sufficiently during the ongoing production process. The graphite felt has a very low thermal conductivity and is formed by fibers needled to one another and/or fiber mixtures connected to one another, between which a more or less large air cushion is formed. In the case of graphite felt, a distinction is made between so-called soft graphite felt and hard graphite felt. The hard graphite felt is mostly formed by mixing and pressing fiber mixtures and binding agents, such as phenolic resin, and a subsequent high-temperature treatment. These felts are, most times, cut to the desired dimensions by means of mechanical processing. A deformation to a larger extent is often no longer possible, wherein the shaping is preferably carried out before the binding agent sets.

The soft graphite felt is formed by fibers, mostly cellulose fibers or the like, needled to one other and subjected to a subsequent thermal treatment. Such felts are simple to adjust in regard to their shape, for example by cutting with a knife or a pair of scissors.

The enveloping unit 206 may comprise at least one layer of the hard graphite felt, as needed. However, it would also be possible that the enveloping unit 206 comprises at least one layer of the soft graphite felt. Regardless of this, however, the enveloping unit 206 may also be formed by at least one layer of the hard graphite felt and by at least one layer of the soft graphite felt. This adumbrated is in dashed lines in FIG. 1. In the case of a multi-layer enveloping unit 206, e.g. the at least one layer of a hard graphite felt may be arranged closer to the crucible 201 than the at least one layer of the soft graphite felt. However, it would also be possible that the at least one layer of the hard graphite felt may be arranged closer to the crucible 201 than the at least one layer of the soft graphite felt.

The fibers of the felt may be short fibers and/or long fibers. The short fibers often have a stretched fiber length selected from a value range having a lower limit of 0.1 mm up to an upper limit of 5 mm. In the case of so-called long fibers, they have a stretched fiber length selected from a value range having a lower limit of larger 5 mm and an upper limit of 15 mm, in particular of 10 mm.

The crucible 201, for its part, is also formed by a temperature-resistant or high-temperature resistant material. In this regard, the material of the crucible 201 may be selected from a group comprising metal-based, oxide-based, nitride-based, carbon-based, and dense graphite. In this regard, these materials may be, for example, silicon (Si), silicon carbide (SiC), aluminum oxide (Al₂O₃), gallium nitride (GaN), or aluminum nitride (A1N). Ceramic materials may also be used.

In order to hold the enveloping unit 206 in a positioned manner directly on the, in most cases, free-standing crucible 201, a separate holding unit 207 is provided here. As the crucible 201 mostly or preferably has a cylindrical or cylinder-like outer surface, which defines the outer lateral surface 203, the enveloping unit 206 can be easily arranged and fastened after the filling of the accommodation space 202 with the base material meant for the formation of the crystals, or it may be removed from the crucible 201 as needed, after the production of the crystals so they can be removed from the crucible 201, in a simple work step by an operator after releasing the holding unit 207.

For this purpose, the holding unit 207 comprises at least one holding element 208, which is wrapped around the outside of the enveloping unit 206 at least once and thus surrounds the enveloping unit 206 in a circumferential manner. The holding element 208 can also be referred to as holding means or clamping means. To this end, the holding element 208 has a longitudinal extension, which is substantially larger than its cross-sectional dimension. Hence, the holding element 208 is designed to be oblong and largely or preferably non-rigid. Depending on the material used for forming the holding element 208, it may also have a certain inherent stiffness.

Furthermore, the at least one holding element 208 is arranged such that it is arranged so as to contact the outside of the enveloping unit 206. The holding element 208 has a first end section 209 and a second end section 210 spaced apart therefrom in its longitudinal extension. For the mutual connection of the holding element 208 designed to be oblong, it is further provided that the first end section 209 and the second end section 210 are coupled to one another. If a circumferential prestressing force is applied to the at least one holding element 208 before it is brought into its coupled position of the two end sections 209, 210, a circumferential contacting on the holding unit 207 takes place. This way, a holding force acting on the enveloping unit 206 in the radial direction is applied and the enveloping unit 206 is pressed against the lateral surface 203 of the crucible 201.

The first end section 209 and the second end section 210 of the at least one holding element 208 may be knotted together to form their coupling connection.

For forming the coupling connection of the two end sections 209, 210 of the holding element 208, a separate coupling device 211 could also be provided. This is schematically shown in a simplified manner. The coupling device 211 may for example be structured similarly to what is sufficiently known in the case of tension belts. However, buckle connections or other clamping devices may also be used.

The at least one holding element 208 is also to be formed by a temperature-resistant or a high-temperature resistant material such as a graphite material. The holding element 208 is furthermore to have a sufficient tensile strength as well as a simple transverse deformability. The holding element 208 designed to be oblong and preferably non-rigid may be selected from the group of cord, rope, strip, belt, chain. The formation of the holding element 208 as a strip or a belt is shown in the region of the bottom section 202, and the formation as a cord or a rope is shown in the region of the opening section 205.

Depending on the constructional height of the crucible 201 and a better, complete envelopment of the crucible 201, it is also possible for multiple holding elements 208 to be provided. In this regard, an arrangement spaced apart from one another in the direction of the axial extension of the crucible 201 may be selected.

In order to achieve a circumferential guide of the at least one holding element 208 on the enveloping unit 206, the holding element 207 may comprise at least one guide element 212, wherein it is also possible that multiple of the guide elements 212 per holding element 208 may be arranged distributed across the circumference. For this purpose, the guide element 212 is or the guide elements 212 are arranged, in particular fastened, on that side of the enveloping unit 206 which faces away from the crucible 201. The at least one guide element 212 is formed or configured to guide the at least one holding element 208 in a predefined relative position with respect to the enveloping unit 206.

The enveloping unit 206 may be designed to be plate-shaped, wherein depending on the chosen design, a preformed cross-sectional shape adapted to the outer cross-section of the crucible 201 can also be selected. In most cases or preferably, at least one separating section or overlap section extending in a mainly parallel orientation with respect to the axial extension is provided.

As can now be seen better in FIG. 2, the enveloping unit 206 preferably has a first longitudinal edge section 213 and a second longitudinal edge section 214 when observed in the circumferential direction. In the insulation position of the enveloping unit 206 on the crucible 201, the two longitudinal edge sections 213, 214 may be arranged so as to overlap in the circumferential direction.

Furthermore, the enveloping unit 206 may jut out beyond the crucible 201 in the direction of its axial extension on at least one side facing away from the crucible 201 and thus protrude beyond it.

The device 200 may moreover also comprise a separate housing 215, which defines an accommodation chamber 216 in its interior. The accommodation chamber 216 is preferably sealed from the outer atmosphere and may also be evacuated to an internal pressure that is lower than that of the outer atmosphere. A transparent material may be used as the material for the housing 215. In this regard, this may be a glass material, in particular a quartz glass. The crucible 201 is accommodated in the accommodation chamber 216 along with the enveloping unit 206.

By providing the additional holding unit 207, it is no longer necessarily required that the intermediate space between the outer surface and/or the lateral surface 203 of the crucible 201 and the inner wall surface of the housing 215 is completely filled by the insulating enveloping unit 206. A distanced arrangement is possible.

Furthermore, a heating device 217 is provided to provide thermal energy for heating the crucible 201, its accommodation space 202 and the base material located therein for forming crystals. The heating device 217 is preferably arranged circumferentially around the housing 215 and is further configured to provide the thermal energy required for the crucible 201.

To provide a better overview, the representation of a control device, an energy supply unit and connection and supply lines was refrained from.

FIG. 3 shows a possible exemplary embodiment of a crucible designed to have multiple parts, which is why for this embodiment, a different reference number is used for the previously described crucible 201, namely the reference number 301. The image shown depicts an axial section in an upright, standing position of the crucible 301.

In the following, only the structure of the crucible 301 will be described, wherein the previously described parts and components for forming the device 200 may also be used in combination with this crucible 301. This is why, in order to avoid unnecessary repetitions, it is pointed to/reference is made to the detailed description in FIGS. 1 and 2 preceding it.

In the exemplary embodiment shown, the crucible 301 comprises a crucible bottom part 302, at least one crucible wall part 302 and a crucible cover part 304. In order to be able to orient the individual components forming the crucible 301 so as to be positioned relative to one another, at least one positioning assembly 305 is provided or formed in this exemplary embodiment. In this case, the positioning assembly 305 is arranged or formed between the crucible bottom part 302, namely a wall section rising up from the bottom, and the at least one crucible wall part 303.

The positioning assembly 305 may be designed in a variety of ways, wherein at least one positioning element each is provided on ends of the crucible bottom part 302 and of the crucible wall part 303, which ends face one another. The positioning elements facing one another are formed or configured to mutually cooperate. The positioning assembly 305 may be designed, for example in the form or type of a tongue and groove joint, projecting and recessed positioning elements or the like.

The exemplary embodiments show possible embodiment variants, and it should be noted in this respect that the invention is not restricted to these particular illustrated embodiment variants of it, but that rather also various combinations of the individual embodiment variants are possible and that this possibility of variation owing to the technical teaching provided by the present invention lies within the ability of the person skilled in the art in this technical field.

The scope of protection is determined by the claims. Nevertheless, the description and drawings are to be used for construing the claims. Individual features or feature combinations from the different exemplary embodiments shown and described may represent independent inventive solutions. The object underlying the independent inventive solutions may be gathered from the description.

All indications regarding ranges of values in the present description are to be understood such that these also comprise random and all partial ranges from it, for example, the indication 1 to 10 is to be understood such that it comprises all partial ranges based on the lower limit 1 and the upper limit 10, i.e. all partial ranges start with a lower limit of 1 or larger and end with an upper limit of 10 or less, for example 1 through 1.7, or 3.2 through 8.1, or 5.5 through 10.

Finally, as a matter of form, it should be noted that for ease of understanding of the structure, elements are partially not depicted to scale and/or are enlarged and/or are reduced in size.

List of reference numbers

| | |
|---|---|
| 200 | Device |
| 201 | Crucible |
| 202 | Receiving space |
| 203 | Lateral surface |
| 204 | Bottom section |
| 205 | Opening section |
| 206 | Enveloping unit |
| 207 | Holding unit |
| 208 | Holding element |
| 209 | First end section |
| 210 | Second end section |
| 211 | Coupling device |
| 212 | Guide element |
| 213 | Longitudinal edge section |
| 214 | Longitudinal edge section |
| 215 | Housing |
| 216 | Accommodation chamber |
| 217 | Heating device |
| 301 | Crucible |
| 302 | Crucible bottom part |
| 303 | Crucible wall part |
| 304 | Crucible cover part |
| 305 | Positioning assembly |

1. A device (200) for growing crystals, comprising
a crucible (201, 301), which crucible (201, 301) defines an outer lateral surface (203) and moreover delimits an accommodation space (202) with an axial extension between a bottom section (204) and an opening section (205), wherein the accommodation space (202) is designed for growing the crystals,
an enveloping unit (206), which enveloping unit (206) covers the outer lateral surface (203) at least in sections and is designed for thermally insulating the crucible (201, 301), wherein
a holding unit (207) is provided, by means of which holding unit (207) the enveloping unit (206) is held on the crucible (201, 301) in its position relative to the crucible (201, 301),
the holding unit (207) comprises at least one holding element (208) designed to be oblong and preferably non-rigid, having a first end section (209) and a second end section (210) spaced apart therefrom in its longitudinal extension,
the at least one holding element (208) surrounds the enveloping unit (206) in a circumferential manner on the side facing away from the crucible (201, 301) and is arranged so as to contact the enveloping unit (206), and
the first end section (209) and the second end section (210) are coupled to one another so as to be releasable as needed, and a holding force acting on the enveloping unit (206) in the radial direction is applied by the at least one holding element (208).

2. The device (200) according to claim 1, wherein the at least one holding element (208) is formed by a graphite material.

3. The device (200) according to claim 1, wherein the first end section (209) and the second end section (210) of the at least one holding element (208) are knotted together.

4. The device (200) according to claim 1, wherein a coupling device (211) is provided for the at least one holding element (208), by means of which coupling device (211) the first end section (209) and the second end section (210) of the at least one holding element (208) are coupled to one another.

5. The device (200) according to claim 1, wherein the holding element (208) designed to be oblong and preferably non-rigid is selected from the group of cord, rope, strip, belt, chain.

6. The device (200) according to claim 1, wherein multiple holding elements (208) are provided and the holding elements (208) are arranged so as to be spaced apart from one another in the direction of the axial extension of the crucible (201, 301).

7. The device (200) according to claim 1, wherein the holding unit (207) comprises at least one guide element (212), which at least one guide element (212) is arranged on the enveloping unit (206) on the side facing away from the crucible (201, 301), and the at least one guide element (212) is configured to guide the at least one holding element (208) in a predefined relative position with respect to the enveloping unit (206).

8. The device (200) according to claim 1, wherein the enveloping unit (206) has a first longitudinal edge section (213) and a second longitudinal edge section (214) when observed in the circumferential direction, and the longitudinal edge sections (213, 214) facing one another are arranged so as to overlap in the circumferential direction.

9. The device (200) according to claim 1, wherein the enveloping unit (206) protrudes beyond the crucible (201, 301) in the direction of its axial extension on at least one side facing away from the crucible (201, 301).

10. The device (200) according to claim 1, wherein the enveloping unit (206) is formed by a graphite felt.

11. The device (200) according to claim 10, wherein the graphite felt comprises at least one layer of a hard graphite felt.

12. The device (200) according to claim 10, wherein the graphite felt comprises at least one layer of a soft graphite felt.

13. The device (200) according to claim 10, wherein the at least one layer of a hard graphite felt is arranged closer to the crucible (201, 301) than the at least one layer of the soft graphite felt.

14. The device (200) according to claim 1, wherein the crucible (201, 301) is formed by a material, which is selected from a group, which comprises metal-based, oxide-based, nitride-based, carbon-based and dense graphite.

15. The device (200) according to claim 1, wherein the crucible (301) is designed to have multiple parts and comprises a crucible bottom part (302), at least one crucible wall part (303) and a crucible cover part (304).

16. The device (200) according to claim 15, wherein a positioning assembly (305) is provided, by means of which positioning assembly (305) at least the crucible bottom part (302) and the at least one crucible wall part (303) are positioned on the ends facing one another oriented in a predefined position relative to one another.

17. The device (200) according to claim 1, wherein a housing (215) is provided, which housing (215) defines an accommodation chamber (216), and the crucible (201, 301) along with the enveloping unit (206) and the holding unit (207) is accommodated in the accommodation chamber (216).

18. The device (200) according to claim 1, wherein a heating device (217) is provided, which heating device (217) is preferably arranged circumferentially around the housing (215) and is configured to provide thermal energy for the crucible (201, 301).
